(19) United States
(12) Patent Application Publication
(10) Pub. No.: US 2026/0013144 A1
(43) Pub. Date: Jan. 8, 2026

(54) SEMICONDUCTOR DEVICE AND MANUFACTURING METHOD THEREFOR

(71) Applicant: XIAMEN INDUSTRIAL TECHNOLOGY RESEARCH INSTITUTE CO., LTD., Xiamen (CN)

(72) Inventors: Taiwei CHIU, Xiamen (CN); Wuxin LI, Xiamen (CN); Tingying SHEN, Xiamen (CN)

(73) Assignee: XIAMEN INDUSTRIAL TECHNOLOGY RESEARCH INSTITUTE CO., LTD., Xiamen (CN)

(21) Appl. No.: 18/993,588

(22) PCT Filed: May 31, 2023
(86) PCT No.: PCT/CN2023/097318

§ 371 Date: Jan. 13, 2025

(30) Foreign Application Priority Data
Dec. 21, 2022 (CN) 202211648266.8

(51) Int. Cl. H10B 63/00; H10N 70/00; H10N 70/20

(52) U.S. Cl. CPC H10B 63/80; H10N 70/023; H10N 70/24; H10N 70/841

(57) ABSTRACT

A semiconductor device and a manufacturing method therefor are provided. The method includes: sequentially depositing a first barrier layer and a first dielectric layer in an array of a metal substrate; etching a first through hole in the first barrier layer and the first dielectric layer in the array, depositing a lower electrode in the first through hole, and performing planarization treatment; sequentially depositing a resistive layer and a second barrier layer on the upper surfaces of the first dielectric layer and the lower electrode; depositing a second dielectric layer on the second barrier layer; etching a second through hole and a wire slot, which are in communication with each other, in each layer on the resistive layer; sequentially depositing an oxygen capture layer and an upper electrode in the second through hole and the wire slot, and then filling a metal wire.

### CROSS REFERENCE TO THE RELATED APPLICATIONS

This application is the national phase entry of International Application No. PCT/CN2023/097318, filed on May 31, 2023, which is based upon and claims priority to Chinese Patent Application No. 202211648266.8, filed on Dec. 21, 2022, the entire contents of which are incorporated herein by reference.

### TECHNICAL FIELD

The present application relates to the technical field of semiconductors, and in particular to a semiconductor device and a manufacturing method therefor.

### BACKGROUND

In the related art, a resistive random access memory (RRAM) is one of the current most promising next-generation non-volatile memories. Compared with the conventional floating gate flash memory, the RRAM has significant advantages in terms of device structure, speed, scalability, three-dimensional integration potential and the like.

The basic structure of the RRAM is a metal-insulator-metal (MIM) structure, which mainly includes a bottom electrode, a resistive layer (also called a resistive switching layer), and a top electrode. The resistive layer is made of various oxide thin film materials, and can transform reversibly between different resistance states under the action of external electrical signals such as voltage and current. The reversible transformation is mostly achieved by the formation and fracture of a conductive filament.

At present, the MIM structure is manufactured by sequentially depositing all thin films and then etching the thin films by using a photomask to obtain a resistive structure (R) (called a stacked resistive structure), the size of the resistive structure (also called resistive switching structure) is defined by the photomask. When the resistive structure is miniatured, if the photomask is too thin or thick, the problems such as tapering of R contours, collapse of array edges, or bridging of metal wires are easily caused.

### SUMMARY

The present application provides a semiconductor device and a manufacturing method therefor, in order to solve the above technical problems.

A first aspect of the present application provides a method for manufacturing a semiconductor device, including:
sequentially depositing a first barrier layer and a first dielectric layer in an array of a metal substrate;
etching a first through hole in the first barrier layer and the first dielectric layer in the array, depositing a lower electrode in the first through hole, and performing planarization treatment to make an upper surface of the lower electrode flush with an upper surface of the first dielectric layer;
sequentially depositing a resistive layer and a second barrier layer on the upper surfaces of the first dielectric layer and the lower electrode in the array;
depositing a second dielectric layer on the second barrier layer in the array;
etching a second through hole and a wire slot, which are in communication with each other, in each layer on the resistive layer in the array; where a bottom of the second through hole is in communication with the resistive layer, and a top of the second through hole is in communication with the wire slot; and
sequentially depositing an oxygen capture layer and an upper electrode in the second through hole and the wire slot, and then filling a metal wire.

The metal substrate may further include a logic; correspondingly, when sequentially depositing the first barrier layer and the first dielectric layer in the array of the metal substrate, the method may further include: sequentially depositing a first barrier layer and a first dielectric layer in the logic of the metal substrate.

When sequentially depositing the resistive layer and the second barrier layer on the upper surfaces of the first dielectric layer and the lower electrode in the array, the method may further include: sequentially depositing a resistive layer and a second barrier layer on the first dielectric layer in the logic.

Before depositing the second dielectric layer on the second barrier layer in the array, the method may further include: removing the resistive layer and the second barrier layer in the logic; correspondingly, when depositing the second dielectric layer on the second barrier layer in the array, the method may further include: depositing a second dielectric layer on the first dielectric layer in the logic.

Before depositing the second dielectric layer on the second barrier layer in the array, the method may further include: removing the first dielectric layer, the resistive layer, and the second barrier layer in the logic; correspondingly, when depositing the second dielectric layer on the second barrier layer in the array, the method may further include: depositing a second dielectric layer on the first barrier layer in the logic.

When etching the second through hole and the wire slot, which are in communication with each other, in each layer on the resistive layer in the array, the method may further include: etching a second through hole and a wire slot in each layer on the metal substrate in the logic.

When sequentially depositing the oxygen capture layer and the upper electrode in the second through hole and the wire slot in the array, the method may further include:
sequentially depositing an oxygen capture layer and an upper electrode in the second through hole and the wire slot of the logic.

A second aspect of the present application provides a semiconductor device including an array, and the array includes:
a metal substrate;
a first barrier layer disposed on the metal substrate, and a first dielectric layer disposed on the first barrier layer;
a first through hole disposed in the first barrier layer and the first dielectric layer, and a lower electrode filled in the first through hole;
a resistive layer disposed on the lower electrode;
a second barrier layer disposed on the resistive layer, and a second dielectric layer disposed on the second barrier layer;
a second through hole and a wire slot disposed in the second barrier layer and the second dielectric layer, where a bottom of the second through hole is in communication with the resistive layer, and a top of the second through hole is in communication with the wire slot;
an oxygen capture layer and an upper electrode that stack and cover the bottom of the second through hole, a side wall of the second through hole, and a side wall of the wire slot; and
a metal wire filled in the second through hole and the wire slot.

Orthographic projections of the second through hole and the first through hole on the metal substrate may overlap.

The semiconductor device may further include a logic, and the logic may include:
a metal substrate;
a first barrier layer disposed on the metal substrate, and a dielectric layer disposed on the first barrier layer, where the dielectric layer includes a first dielectric layer and a second dielectric layer, or the dielectric layer is a second dielectric layer;
a second through hole and a wire slot disposed in the first barrier layer and the dielectric layer;
an oxygen capture layer and an upper electrode that stack and cover a bottom of the second through hole, a side wall of the second through hole, and a side wall of the wire slot; and
a metal wire filled in the second through hole and the wire slot.

The size of the resistive structure in the present application is determined by an overlap area of the orthographic projections of the second through hole and the first through hole on the metal substrate, so that the size of the resistive structure in the present application depends on the sizes of the second through hole and the first through hole. The resistive structure in the present application is formed by first depositing the second barrier layer in the array, then forming the second dielectric layer, forming the second through hole in the second barrier layer and the second barrier layer, and depositing the oxygen capture layer and the upper electrode, so that the first formed second dielectric layer and second barrier layer provide firm support for the resistive structure. In addition, the second barrier layer and the second dielectric layer are deposited on a plane, no voids will be produced, and the adjacent resistive structures are completely isolated, compared with a manufacturing method for a stacked resistive structure, tapering of contours of the existing stacked resistive structure, collapse of array edges, bridging of metal wires and other problems can be avoided.

### BRIEF DESCRIPTION OF THE DRAWINGS

By reading the following detailed description with reference to the accompanying drawings, the above and other objectives, features and advantages of exemplary embodiments of the present application will become easier to understand. In the drawings, several embodiments of the present application are shown in an exemplary and non-limiting manner.

In the drawings, the same or corresponding reference numerals denote the same or corresponding parts.

FIG. 1 illustrates a schematic diagram of a first barrier layer and a first dielectric layer in an example of the present application.

FIG. 2 illustrates a schematic diagram of a lower electrode in an example of the present application.

FIG. 3 illustrates a schematic diagram of a resistive layer and a second barrier layer in an example of the present application.

FIG. 4 illustrates a structural diagram of a logic in an example of the present application.

FIG. 5 illustrates a structural diagram of a logic in another example of the present application.

FIG. 6 illustrates a schematic diagram of a second dielectric layer in an example of the present application.

FIG. 7 illustrates a schematic diagram of a second dielectric layer in another example of the present application.

FIG. 8 illustrates a schematic diagram of a second through hole and a metal wire slot/wiring duct in an example of the present application.

FIG. 9 illustrates a schematic diagram of an oxygen capture layer, an upper electrode, and a metal wire in an example of the present application.

FIG. 10 illustrates a schematic diagram of a semiconductor structure provided in an example of the present application.

### DETAILED DESCRIPTION OF THE EMBODIMENTS

In order to make the objectives, features, and advantages of the present application more apparent and easier to understand, the technical solutions in the embodiments of the present application will be clearly and completely described below with reference to the accompanying drawings in the embodiments of the present application. Apparently, the described embodiments are merely a part rather than all of the embodiments of the present application. On the basis of the embodiments in the present application, all other embodiments obtained by those skilled in the art without creative efforts shall fall within the protection scope of the present application.

In the description of this specification, the description referring to the terms “an embodiment”, “some embodiments”, “an example”, “a specific example”, or “some examples” means that specific features, structures, materials, or characteristics described in conjunction with the embodiments or examples are included in at least one embodiment or example of the present application. Moreover, the described specific features, structures, materials, or characteristics can be combined in any one or more embodiments or examples in an appropriate manner. In addition, in the case of no mutual contradiction, those skilled in the art can incorporate and combine different embodiments or examples and features of different embodiments or examples in the description.

Moreover, the terms “first” and “second” are merely used for a description purpose, and cannot be interpreted as indicating or implying relative importance or implicitly indicating the quantity of the indicated technical features. Therefore, the features defined by “first” and “second” can explicitly or implicitly include at least one feature. In the description of the present application, the term “a plurality of” means two or more than two, unless otherwise specified.

An example of the present application provides a method for manufacturing a semiconductor device, two embedded through holes bear an upper electrode and a lower electrode separately, so that the size of a resistive structure can be defined by controlling the sizes of the two through holes. On this basis, the resistive structure can be miniaturized by reducing the sizes of the through holes.

In an example of the present application, the manufacturing of a semiconductor device is divided into an array (also called a storage area) and a logic (also called a logical region) for explanation, where the resistive structure is disposed in the array.

The method for manufacturing a semiconductor device in an example of the present application will be described below with reference to the accompanying drawings. The method includes:

Step 101, sequentially depositing a first barrier layer 20 and a first dielectric layer 30 in an array of a metal substrate 10.

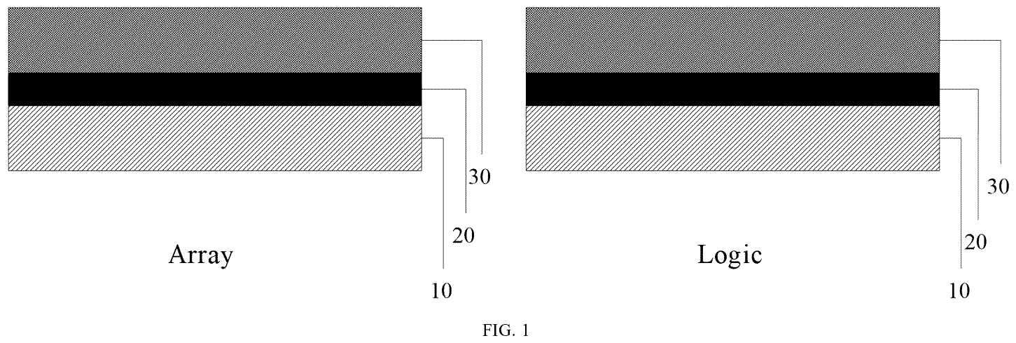

As shown in FIG. 1, the left view represents an array, and the right view represents a logic. When the first barrier layer 20 and the first dielectric layer 30 are deposited in the array of the metal substrate 10, a first barrier layer 20 and a first dielectric layer 30 may also be sequentially deposited in a logic.

The material of the first barrier layer 20 may be nitride doped carbon (NDC), which is used to prevent the metal of the metal substrate 10 from diffusing into the first dielectric layer 30 to affect the performance of the device. The material of the first dielectric layer 30 may be oxide.

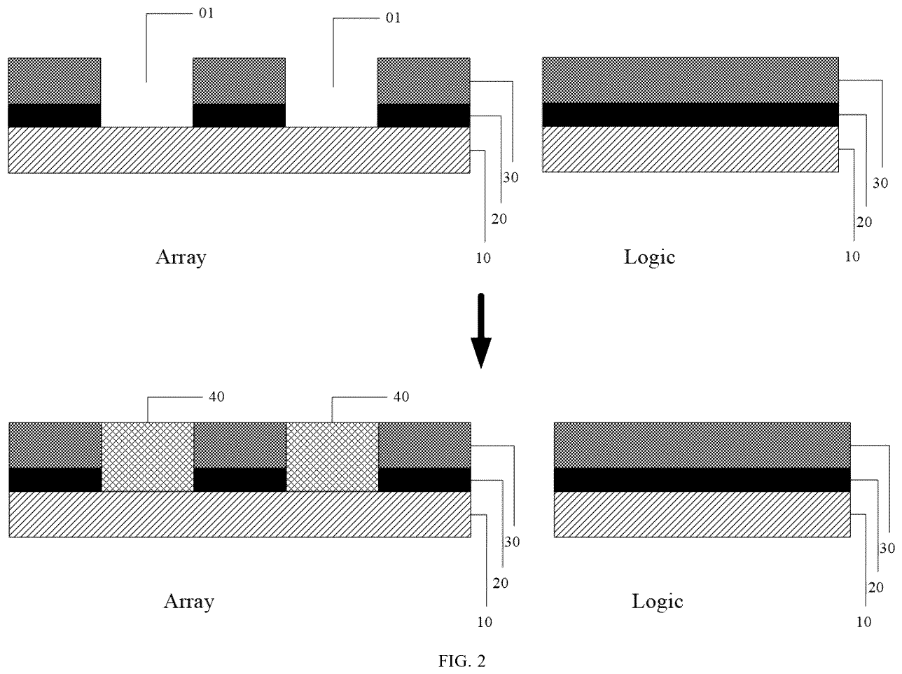

Step 102, etching a first through hole 01 in the first barrier layer 20 and the first dielectric layer 30 in the array, depositing a lower electrode 40 in the first through hole 01, and performing planarization treatment to make an upper surface of the lower electrode 40 flush with an upper surface of the first dielectric layer 30, as shown in FIG. 2.

In this step, the etching of the first through hole 01 and the deposition of the lower electrode 40 are only for the array, therefore, the layers already formed in the logic are not changed.

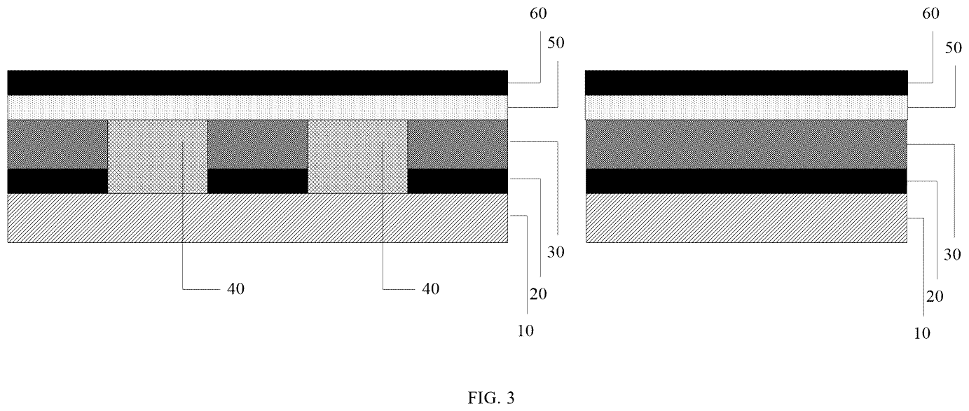

Step 103, sequentially depositing a resistive layer 50 and a second barrier layer 60 on the upper surfaces of the first dielectric layer 30 and the lower electrode 40 in the array, as shown in FIG. 3.

Meanwhile, a resistive layer 50 and a second barrier layer 60 are also sequentially deposited on the first dielectric layer 30 in the logic, as shown in FIG. 3.

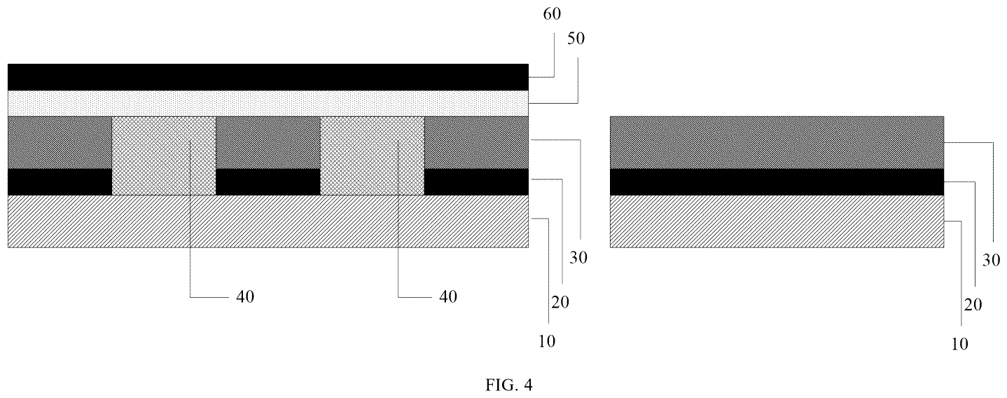

Since the resistive structure needs to be formed only in the array, in an example of the present application, the resistive layer 50 and the second barrier layer 60 in the logic can be removed, as shown in FIG. 4.

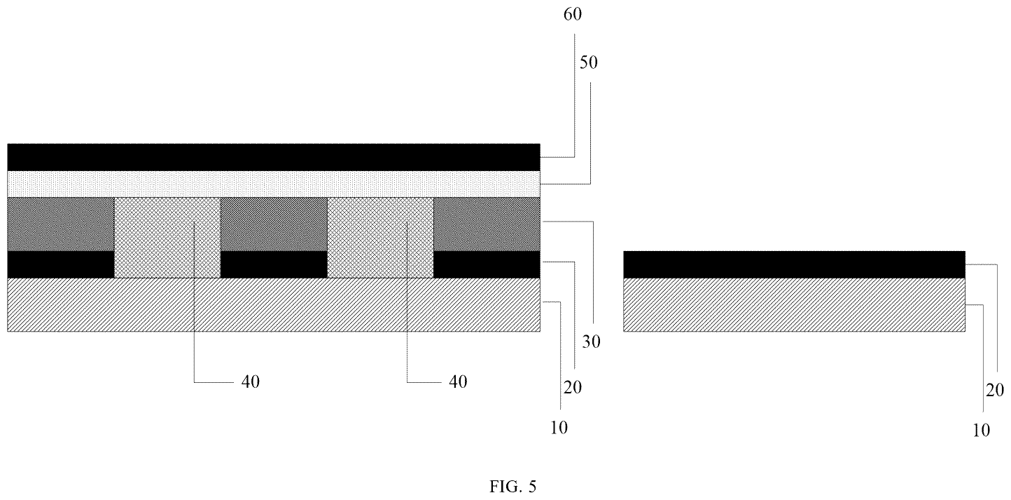

In another example, the first dielectric layer 30 in the logic can also be removed, as shown in FIG. 5. Since another dielectric layer needs to be deposited in the subsequent process, these two dielectric layers in the logic are adjacent. However, because the two dielectric layers are not deposited once, differences in material and process may lead to different dielectric constants of the two dielectric layers, which may affect the performance of the device. Therefore, when the resistive layer 50 and the second barrier layer 60 in the logic are removed, the first dielectric layer 30 can also be removed together.

As shown in FIG. 4, retaining the first dielectric layer 30 can reduce the height difference between the logic and the array. Compared with removing the first dielectric layer 30, an etching process window of the logic can be prevented from becoming smaller. In addition, the second barrier layer 60 in the array can also be used as an etching stop layer, which can further reduce the height difference between the logic and the array and increase the etching process window of the logic.

The material of the resistive layer 50 may be transition metal oxide (TMO), and the resistive layer 50 can be deposited by using an atomic layer deposition (ALD) growth method.

The material of the second barrier layer 60 may be any of NDC, nitride, or aluminum oxide (AlOx).

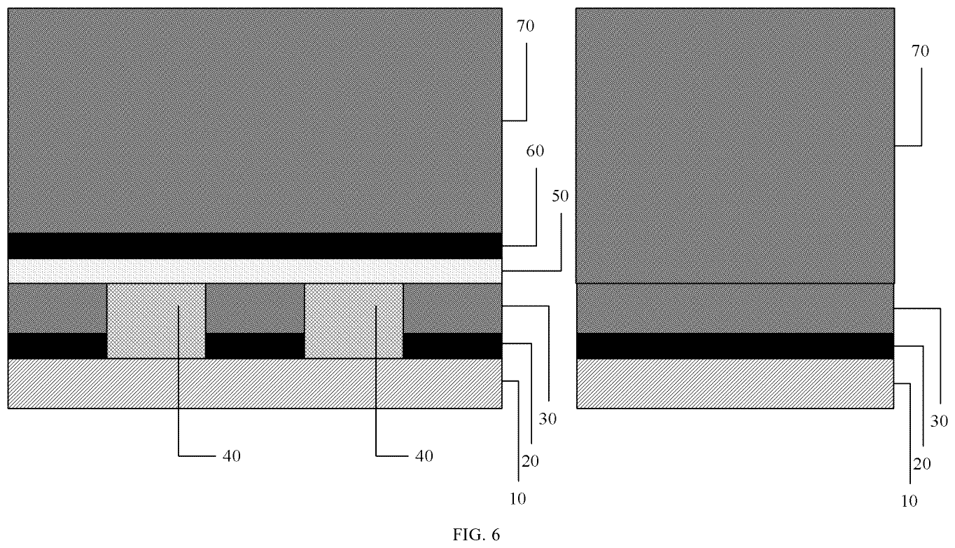

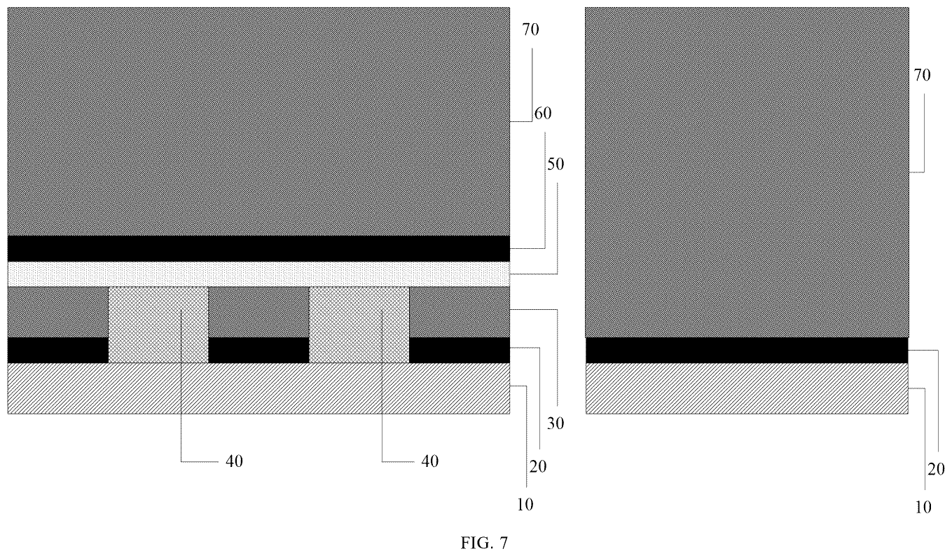

Step 104, depositing a second dielectric layer 70 on the second barrier layer 60 in the array. Meanwhile, corresponding to the structure of the logic shown in FIG. 4, a second dielectric layer 70 may be deposited on the first dielectric layer 30 in the logic, as shown in FIG. 6; corresponding to the structure of the logic shown in FIG. 5, a second dielectric layer 70 may be deposited on the first barrier layer 20 in the logic, as shown in FIG. 7.

The material of the second dielectric layer 70 may be an ultra low K (ULK) dielectric constant material.

As shown in FIG. 6 and FIG. 7, after the second dielectric layer 70 is deposited in the array and the logic, planarization is performed (such as by using a chemical mechanical polishing (CMP) technology), and then overall structures of the array and the logic have the same height, which can ensure that the etching process windows of the two areas are consistent subsequently.

Step 105, etching a second through hole 02 and a metal wire slot 03 (referred to as a wire slot 03), which are in communication with each other, in each layer on the resistive layer 50 in the array. A bottom of the second through hole 02 is in communication with the resistive layer 50, and a top of the second through hole 02 is in communication with the wire slot 03.

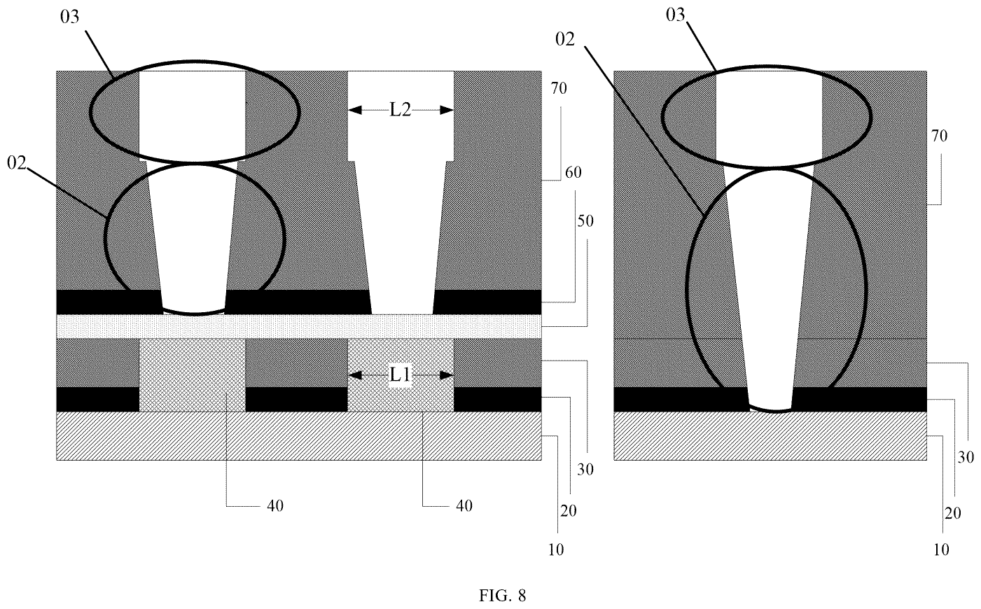

As shown in FIG. 8, the second through hole 02 and the metal wire slot 03 are etched in the second barrier layer 60 and the second dielectric layer 70 (i.e., each layer on the resistive layer 50) in the array.

Meanwhile, the second through hole 02 and the wire slot 03 are etched in each layer on the metal substrate 10 in the logic. Corresponding to the structure shown in FIG. 6, the second through hole 02 and the wire slot 03 are etched in the first barrier layer 20, the first dielectric layer 30, and the second dielectric layer 70, as shown in FIG. 8. Corresponding to the structure shown in FIG. 7, the second through hole 02 and the wire slot 03 are etched in the first barrier layer 20 and the second dielectric layer 70.

The second through hole 02 is disposed directly above the lower electrode 40, that is, orthographic projections of the second through hole 02 and the lower electrode 40 on the metal substrate 10 overlap.

Step 106, sequentially depositing an oxygen capture layer 80 and an upper electrode 90 in the second through hole 02 and the wire slot 03 in the array, and then filling a metal wire material.

Meanwhile, an oxygen capture layer 80 and an upper electrode 90 are sequentially deposited in the second through hole 02 and the wire slot 03 of the logic, after that, a metal wire material is filled.

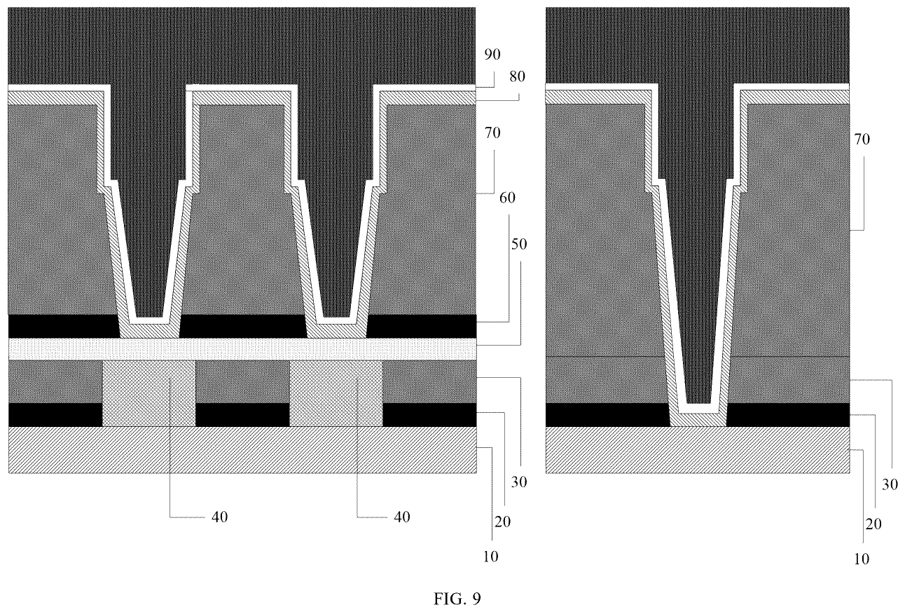

Based on the structure formed in FIG. 8, the oxygen capture layer 80 is first deposited, and then the upper electrode 90 is deposited. The material of the oxygen capture layer 80 may be titanium (Ti) or tantalum (Ta), the oxygen capture layer 80 is grown on the structure shown in FIG. 8 by using a physical vapor deposition (PVD) technology; as shown in FIG. 9, the oxygen capture layer 80 covers a surface of the second dielectric layer 70, the bottom of the second through hole 02, and side walls of the second through hole 02 and the wire slot 03. The material of the upper electrode may be tantalum nitride (TaN), and the upper electrode 90 is grown randomly on the oxygen capture layer 80 by using the ALD technology, as shown in FIG. 9. Correspondingly, after the upper electrode 90 is deposited, a space is formed in the second through hole 02 and the wire slot 03, which is filled with the metal material (such as copper) by means of electroplating and is used as a metal wire.

As such, in the array, the lower electrode 40, the resistive layer 50, the oxygen capture layer 80 and the upper electrode 90 at the bottom of the second through hole 02 form the resistive structure of the present application.

The size of the resistive structure is determined by the size of an overlap area of orthographic projections of the upper electrode 90 at the bottom of the second through hole 02 and the lower electrode 40 on the metal substrate 10. The size of the upper electrode 90 at the bottom of the second through hole 02 is determined by the sizes of the second through hole 02 and the wire slot 03, while the size of the lower electrode 40 is determined by the size of the first through hole 01. Preferably, as shown in FIG. 8, L2 represents a cross-sectional size of the wire slot 03 and the second through hole 02, L2 may be set by the minimum size of the metal wire, and the cross-sectional size L1 of the first through hole 01 may be a minimum size achievable by the process level, thereby achieving the miniaturization of the resistive structure. In addition, the distance between every two adjacent first through holes 01 and the distance between every two adjacent second through holes 02 (wire slots 03) may also be minimum distances achievable by the process level, which can improve the integration of the semiconductor device.

In the logic, the oxygen capture layer 80 and the upper electrode 90 are both barrier layers used for preventing the metal filled in the second through hole 02 and the wire slot 03 from diffusing to the surrounding area.

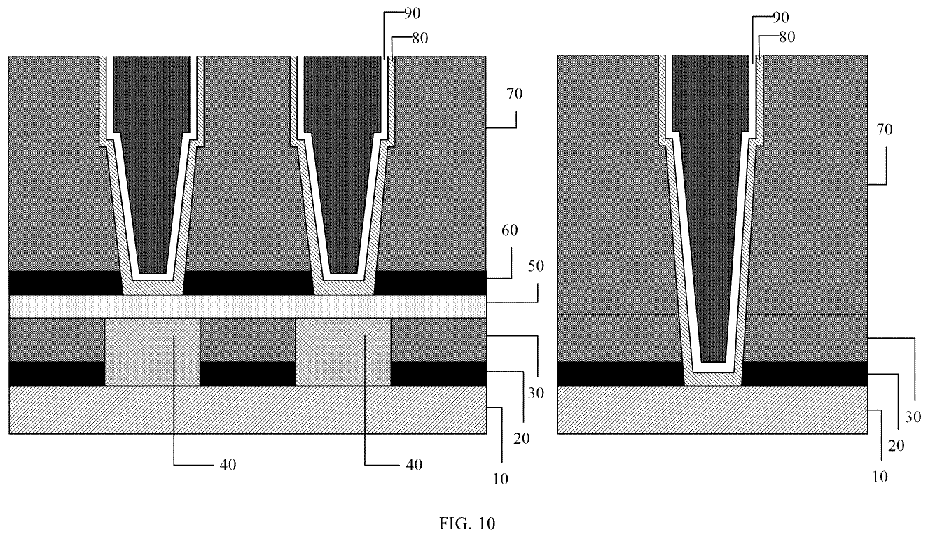

Based on the structure shown in FIG. 9, after the metal material is filled, planarization treatment is performed to remove the oxygen capture layer 80, the upper electrode 90, and the metal material outside the second through hole 02 and the wire slot 03, so that upper surfaces of the second dielectric layer 70, the oxygen capture layer 80, the upper electrode 90, and the metal wire are flush, as shown in FIG. 10.

A semiconductor device provided in the present application will be further explained below based on FIG. 10.

As shown in FIG. 10, a semiconductor device provided in the present application includes an array, and the array includes:
a metal substrate 10;
a first barrier layer 20 disposed on the metal substrate 10, and a first dielectric layer 30 disposed on the first barrier layer 20;
a first through hole 01 disposed in the first barrier layer 20 and the first dielectric layer 30, and a lower electrode 40 filled in the first through hole 01; where there are multiple lower electrodes 40, and every two adjacent lower electrodes 40 are isolated by the first dielectric layer 30;
a resistive layer 50 disposed on the lower electrode 40, where the resistive layer 50 is a connected region that covers not only the lower electrode 40 but also the first dielectric layer 30; it can be seen that the resistive layer 50 is not etched or cut in the present application, which can prevent the resistive layer 50 from being damaged, avoid affecting the formation of a conductive filament, and ensure the performance of the resistive structure;
a second barrier layer 60 disposed on the resistive layer 50, and a second dielectric layer 70 disposed on the second barrier layer 60;
a second through hole 02 and a wire slot 03 disposed in the second barrier layer 60 and the second dielectric layer 70, where a bottom of the second through hole 02 is in communication with the resistive layer 50, and a top of the second through hole 02 is in communication with the wire slot 03;
an oxygen capture layer 80 and an upper electrode 90 that stack and cover the bottom of the second through hole 02, a side wall of the second through hole 02, and a side wall of the wire slot 03; and
a metal wire filled in the second through hole 02 and the wire slot 03.

Orthographic projections of the second through hole 02 and the first through hole 01 on the metal substrate 10 overlap (namely, the second through hole 02 is disposed directly above the first through hole 01). As such, the lower electrode 40, the resistive layer 50, the oxygen capture layer 80 and the upper electrode 90 at the bottom of the second through hole 02 form the resistive structure. Hence, the resistive structures are isolated by the first formed dielectric layers (the first dielectric layer and the second dielectric layer), which can avoid voids formed by first isolation and then filling of a dielectric material between existing stacked resistive structures, thereby avoiding the problem of bridging of the metal wire. In addition, the dielectric layers form firm support for the resistive structure.

Moreover, the size of the resistive structure in the present application is determined by an overlap area of the orthographic projections of the second through hole 02 and the first through hole 01 on the metal substrate 10. Therefore, the size of the resistive structure in the present application depends on the sizes of the second through hole 02 and the first through hole 01.

The stacked resistive structure in the related art is obtained by sequentially depositing all thin films and etching the thin films by means of a photomask, and then the gaps between the resistive structures are filled with dielectric layers. Therefore, contours of the stacked resistive structure obtained by etching are prone to tapering, and array edges are prone to collapse. The resistive structure of the present application includes the lower electrode 40 in the first through hole 01, the middle resistive layer 50, and the oxygen capture layer 80 and the upper electrode 90 in the second through hole 02, and is a sandwich structure that does not require etching and can avoid the problems that the contours of the stacked resistive structure are prone to tapering and the array edges are prone to collapse.

As shown in FIG. 10, the semiconductor device provided in the present application further includes a logic, and the logic includes:
a metal substrate 10;
a first barrier layer 20 disposed on the metal substrate 10, and a dielectric layer disposed on the first barrier layer 20; where the dielectric layer includes a first dielectric layer 30 and a second dielectric layer 70 (corresponding to FIG. 6), or the dielectric layer is a second dielectric layer 70 (corresponding to FIG. 7);
a second through hole 02 and a wire slot 03 disposed in the first barrier layer 20 and the dielectric layer;
an oxygen capture layer 80 and an upper electrode 90 that stack and cover a bottom of the second through hole 02, a side wall of the second through hole 02, and a side wall of the wire slot 03; and
a metal wire filled in the second through hole 02 and the wire slot 03.

Here, the oxygen capture layer 80 and the upper electrode 90 in the logic is used to block the diffusion of metal from the metal wire to a surrounding area to affect the performance of the device. The oxygen capture layer 80 and the upper electrode 90 in the array not only serve as portions of the resistive structure, but also have the function of blocking the diffusion of metal from the metal wire to the surrounding area.

It should be noted that the terms “include”, “contain”, or any other variations thereof herein are intended to encompass non-exclusive inclusions, so that a process, method, article, or apparatus including a series of elements not only includes those elements, but also includes other elements which are not explicitly listed, or also includes inherent elements of the process, method, article, or apparatus. In the absence of more limitations, the element defined by the statement “including a . . . ” does not exclude the existence of other identical elements in the process, method, article, or apparatus that includes that element.

The above description is intended to enable any skilled person in the art to implement and use the content of the present application, and to provide the content in specific applications and required context. Moreover, for the purpose of illustration and description only, the aforementioned descriptions of the embodiments of the present application are provided. The descriptions are not intended to be exhaustive or to limit the present application to the disclosed form. Therefore, many modifications and variations will be apparent to skilled practitioners in the art, and the general principles defined herein may be applied to other embodiments and applications without departing from the essence and scope of the present application. In addition, the discussions of the aforementioned embodiments are not intended to limit the scope of the present application. Therefore, the present application is not intended to be limited to the shown embodiments, but is to be given the widest scope consistent with the principles and novel features disclosed herein.

What is claimed is:

1. A method for manufacturing a semiconductor device, comprising:
sequentially depositing a first barrier layer and a first dielectric layer in an array of a metal substrate;
etching a first through hole in the first barrier layer and the first dielectric layer in the array, depositing a lower electrode in the first through hole, and performing planarization treatment to make an upper surface of the lower electrode flush with an upper surface of the first dielectric layer;
sequentially depositing a resistive layer and a second barrier layer on the upper surface of the first dielectric layer and the upper surface of the lower electrode in the array;
depositing a second dielectric layer on the second barrier layer in the array;
etching a second through hole and a wire slot in each layer on the resistive layer in the array, wherein the second through hole and the wire slot are in communication with each other; wherein a bottom of the second through hole is in communication with the resistive layer, and a top of the second through hole is in communication with the wire slot; and
sequentially depositing an oxygen capture layer and an upper electrode in the second through hole and the wire slot, and then filling a metal wire.

2. The method according to claim 1, wherein the metal substrate further comprises a logic;
correspondingly, when sequentially depositing the first barrier layer and the first dielectric layer in the array of the metal substrate, the method further comprises:
sequentially depositing a first barrier layer and a first dielectric layer in the logic of the metal substrate.

3. The method according to claim 2, wherein when sequentially depositing the resistive layer and the second barrier layer on the upper surface of the first dielectric layer and the upper surface of the lower electrode in the array, the method further comprises:
sequentially depositing a resistive layer and a second barrier layer on the first dielectric layer in the logic.

4. The method according to claim 3, wherein
before depositing the second dielectric layer on the second barrier layer in the array, the method further comprises:
removing the resistive layer and the second barrier layer in the logic;
correspondingly, when depositing the second dielectric layer on the second barrier layer in the array, the method further comprises:
depositing a second dielectric layer on the first dielectric layer in the logic.

5. The method according to claim 3, wherein
before depositing the second dielectric layer on the second barrier layer in the array, the method further comprises:
removing the first dielectric layer, the resistive layer, and the second barrier layer in the logic;
correspondingly, when depositing the second dielectric layer on the second barrier layer in the array, the method further comprises:
depositing a second dielectric layer on the first barrier layer in the logic.

6. The method according to claim 4, wherein when etching the second through hole and the wire slot in each layer on the resistive layer in the array, the method further comprises:
etching a second through hole and a wire slot in each layer on the metal substrate in the logic.

7. The method according to claim 6, wherein when sequentially depositing the oxygen capture layer and the upper electrode in the second through hole and the wire slot in the array, the method further comprises:
sequentially depositing an oxygen capture layer and an upper electrode in the second through hole and the wire slot of the logic.

8. A semiconductor device, comprising an array; wherein the array comprises:
a metal substrate;
a first barrier layer disposed on the metal substrate, and a first dielectric layer disposed on the first barrier layer;
a first through hole disposed in the first barrier layer and the first dielectric layer, and a lower electrode filled in the first through hole;
a resistive layer disposed on the lower electrode;
a second barrier layer disposed on the resistive layer, and a second dielectric layer disposed on the second barrier layer;
a second through hole and a wire slot disposed in the second barrier layer and the second dielectric layer, wherein a bottom of the second through hole is in communication with the resistive layer, and a top of the second through hole is in communication with the wire slot;
an oxygen capture layer and an upper electrode, wherein the oxygen capture layer and the upper electrode stack and cover the bottom of the second through hole, a side wall of the second through hole, and a side wall of the wire slot; and
a metal wire filled in the second through hole and the wire slot.

9. The semiconductor device according to claim 8, wherein orthographic projections of the second through hole and the first through hole on the metal substrate overlap.

10. The semiconductor device according to claim 8, further comprising a logic;
wherein the logic comprise:
a metal substrate;
a first barrier layer disposed on the metal substrate, and a dielectric layer disposed on the first barrier layer, wherein the dielectric layer comprises a first dielectric layer and a second dielectric layer, or the dielectric layer is a second dielectric layer;
a second through hole and a wire slot disposed in the first barrier layer and the dielectric layer;
an oxygen capture layer and an upper electrode that stack and cover a bottom of the second through hole, a side wall of the second through hole, and a side wall of the wire slot; and
a metal wire filled in the second through hole and the wire slot.

11. The method according to claim 5, wherein when etching the second through hole and the wire slot in each layer on the resistive layer in the array, the method further comprises:
etching a second through hole and a wire slot in each layer on the metal substrate in the logic.

12. The method according to claim 11, wherein when sequentially depositing the oxygen capture layer and the upper electrode in the second through hole and the wire slot in the array, the method further comprises:
sequentially depositing an oxygen capture layer and an upper electrode in the second through hole and the wire slot of the logic.
